(19) United States
(12) Patent Application Publication
(10) Pub. No.: US 2006/0055438 A1
(43) Pub. Date: Mar. 16, 2006

(54) Power-on reset circuit

(76) Inventors: Yongcong Chen, Taipei (TW); Zhen-Yu Song, Taipei (TW); Ken-Ming Li, Taipei (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 10/940,085

(22) Filed: Sep. 14, 2004

(51) Int. Cl. H03L 7/00

(52) U.S. Cl. 327/143

(57) ABSTRACT

A power-on reset circuit for use in an integrated circuit. The power-on reset circuit comprises an inverter, a switch means, and a number of diode-connected transistors. The switch means having a control terminal connected to an output terminal of the inverter is coupled between a power supply and an input terminal of the inverter. The diode-connected transistors are connected in series between the power supply and the input terminal of the inverter. The power-on reset circuit also comprises another diode-connected transistor connected between the input terminal of the inverter and a circuit ground. This diode-connected transistor is preferably connected in inverse series with the remaining diode-connected transistors.

### BACKGROUND OF THE INVENTION

1. Field of the Invention

The invention relates to integrated circuits (ICs), and more particularly to a power-on reset circuit used in an IC chip for initializing internal circuitry thereof following system power-up.

2. Description of the Related Art

Power-on reset circuits are commonly used in electronic circuit design to indicate when the power supply voltage has reached an operational level for an integrated circuit following system power-up. After a system is turned on, a supply voltage generally ramps up to a steady voltage level over a period of time. Until system power supplies reach a desired voltage level, individual circuits and devices as a whole behave unpredictably. Today's very large scale integrated (VLSI) circuits may contain thousands or millions of transistors, registers, latches, and flip-flops which store state information. These circuit elements must be properly initialized or reset prior to functional operation. Initialization is often performed by means of a power-on reset signal.

A power-on reset signal is a digital signal that is asserted while external power is being applied to a chip or integrated circuit. The power-on reset signal drives the set or reset inputs of, for example, flip-flops to initialize the state of the integrated circuit to a predefined and known condition. Most related art power-on reset circuits produce the reset signal using time delay schemes. Referring to FIG. 1, a conventional power-on reset circuit 100 is illustrated. The circuit 100 is made up of a delay circuit 110 and a buffer 120. The delay circuit 110 includes a resistor 112 and a capacitor 114 that cooperate to form an RC delay. The buffer 120 includes two Schmitt-trigger gates 122 and 124. The power-on reset circuit 100 works well in simulation, assuming that the supply voltage, V_{DD}, rises quickly and monotonically to its maximum value and remains there. Under these conditions, the circuit 100 adopts an RC time constant large enough to guarantee that the Schmitt-trigger gates 122 and 124 hold the output, ˜RESET, low (active) for any specified time after V_{DD} stabilized. Upon the RC time-out, ˜RESET goes high (inactive), commencing normal operations.

However, there are several problems in the power-on reset circuit 100 utilizing a capacitor. First, the capacitor must be large enough to ensure an adequate RC delay, but a bulky capacitor wastes a considerable portion of the circuit area. Second, the power-on reset circuit 100 cannot function properly when a short power interruption occurs. One reason for such a malfunction is that the power interruption is not long enough to discharge the RC circuit, thus residual charges on the capacitor prevent the power-on reset circuit from proper activation. This leads other circuit elements such as flip-flops to an invalid state even when the supply voltage has recovered. Furthermore, the presence of electrostatic discharge (ESD) devices, which are included to protect a chip from destructive static discharge events, may give rise to other difficulties. Many types of integrated circuits are manufactured to include logic operating at different voltage levels. To protect against ESD events, a number of diodes are usually coupled between the various power supply lines. In this environment, an on-chip power-on reset circuit, such as the circuit 100, cannot function properly when a correct power-up sequence is unsatisfied. Therefore, what is needed is an on-chip power-on reset circuit without use of a capacitor, unencumbered by the limitations associated with related arts.

### SUMMARY OF THE INVENTION

The present invention is generally directed to an on-chip power-on reset circuit. According to one aspect of the invention, the power-on reset circuit comprises an inverter and a switch means. The switch means having a control terminal connected to an output terminal of the inverter is coupled between a power supply and an input terminal of the inverter. The power-on reset circuit also comprises a plurality of diode-connected transistors connected in series and another diode-connected transistor in inverse series connection therewith. The diode-connected transistor in inverse series connection is coupled between the input terminal of the inverter and a circuit ground, while the remaining diode-connected transistors are coupled between the power supply and the input terminal of the inverter.

According to another aspect of the invention, an apparatus for generating a reset signal used in an integrated circuit upon power-on is disclosed. The apparatus of the invention comprises a plurality of diode-connected transistors connected in series between a power supply and a junction, as well as another diode-connected transistor connected in inverse series therewith and between the junction and a circuit ground. The apparatus of the invention also incorporates a latch coupled to the junction. When the output of the power supply exceeds an operational voltage, the latch can maintain the reset signal at a predetermined logic level.

According to yet another aspect of the invention, an apparatus for generating a reset signal comprises a latch, diode-connected transistor, and load means. The diode-connected transistor is preferably arranged to be reverse-biased and connected between a junction and circuit ground. The load means is connected between a power supply and the junction. The latch is coupled to the load means and the diode-connected transistor at the junction. When the output of the power supply exceeds an operational voltage, the latch is responsible for latching the reset signal at a predetermined logic level.

### DESCRIPTION OF THE DRAWINGS

The present invention will be described by way of exemplary embodiments, but not limitations, illustrated in the accompanying drawings in which like references denote similar elements, and in which:

FIG. 1 is a schematic diagram of a conventional power-on reset circuit;

FIG. 2 is a schematic diagram of a power-on reset circuit according to an embodiment of the invention; and

FIG. 3 is a resistance-voltage characteristic graph useful in understanding the invention.

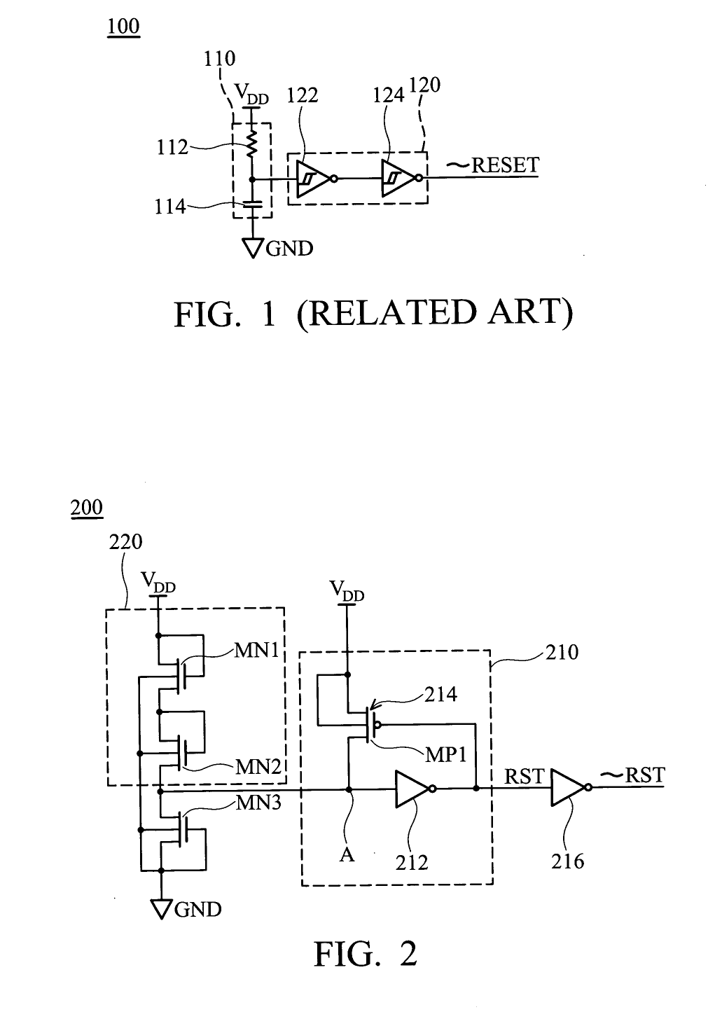

### DETAILED DESCRIPTION OF THE INVENTION

Reference throughout this specification to “one embodiment” or “an embodiment” indicates that a particular feature, structure, or characteristic described in connection with the embodiments is included in at least one embodiment of the present invention. Thus, the appearance of the phrases “in one embodiment” or “an embodiment” in various places throughout this specification is not necessarily all referring to the same embodiment. Furthermore, the particular features, structures, or characteristics may be combined in one or more embodiments. As to the accompanying drawings, it should be appreciated that not all components necessary for a complete implementation of a practical system are illustrated or described in detail. Rather, only those components necessary for a thorough understanding of the invention are illustrated and described. Furthermore, components which are either conventional or may be readily designed and fabricated according to the teachings provided herein are not described in detail.

Referring to FIG. 2, an embodiment of a power-on reset circuit according to the invention is illustrated. The power-on reset circuit 200 is mainly made up of a latch 210, diode-connected transistor MN3, and load means 220. Each transistor described herein is either a p-channel or n-channel MOS transistor having a gate, a drain and a source. Since a MOS transistor is typically a symmetrical device, the true designation of “source” and “drain” is only possible once a voltage is impressed on the terminals. The designations of source and drain herein should be interpreted, therefore, in the broadest sense. As depicted, the diode-connected transistor MN3 is preferably arranged to be reverse-biased and connected between a junction A and circuit ground GND. The load means 220 connects a power supply V_{DD} to the junction A. The latch 210 is coupled to the load means 220 and the diode-connected transistor MN3 at the junction A. When the output of the power supply V_{DD} exceeds an operational voltage, the latch 210 maintains a signal RST at a predetermined logic level to improve noise immunity. Furthermore, the power-on reset circuit 200 includes an inverter 216 receiving the signal RST at its input and producing a reset signal ˜RST. Here active low signals are denoted by a “˜” at the beginning of the signal name.

The power-on reset circuit 200 of the invention is now discussed more fully with continued reference to FIG. 2. The latch 210 comprises an inverter 212 and switch means 214. The inverter 212 is connected between the junction A and the inverter 216. The switch means 210, having a control terminal connected to an output terminal of the inverter 212, is coupled between the power supply V_{DD} and an input terminal of the inverter 212. In one embodiment, the switch means 210 comprises a PMOS transistor MP1 having its gate connected to the control terminal, its source connected to the power supply V_{DD}, and its drain connected to the input terminal of the inverter 212. Generally, the PMOS transistor MP1 has its body, or substrate, connected to the most positive potential, i.e. the power supply V_{DD}. The load means 220 is formed by two diode-connected transistors MN1 and MN2 connected in series between the power supply V_{DD} and the input terminal of the inverter 212. Other components such as resistors may be used to form the load means 220, but the series connected transistors are more space efficient. The diode-connected transistor MN3 is reverse-biased as stated earlier such that it is connected in inverse series with the other diode-connected transistors MN1 and MN2. The diode-connected transistor MN3, the load means 220 and the input terminal of the inverter 212 are jointly connected at the junction A. In FIG. 2, the diode-connected transistors are each implemented with a common drain-gate connected NMOS transistor. Additionally, all of the NMOS transistors MN1-MN3 generally have their body connected to the most negative potential, i.e. the circuit ground GND. It should be understood to those skilled in the art that other transistor technologies are contemplated for implementing the transistors illustrated in FIG. 2 by the principles of the invention.

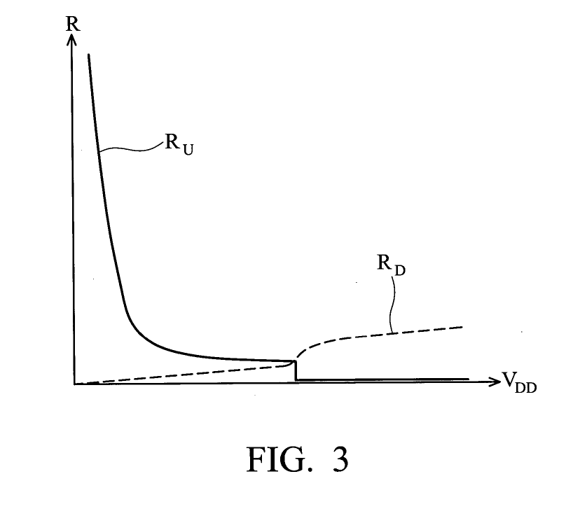

The load means 220 and the transistor MN3 form equivalent resistance R_{U} and R_{D} respectively after application of the supply voltage. Referring to FIG. 3, a resistance-voltage characteristic graph is illustrated in relation to R_{U} and R_{D}. Initially, the diode-connected transistors MN1 and MN2 operate in a cutoff region so the equivalent resistance R_{U} is very large. Therefore, a voltage V_{A} developed at the junction A tracks the supply voltage V_{DD} shortly after the power supply begins ramping. The NMOS transistors MN1 and MN2 have the same threshold voltage V_{T}. As the supply voltage V_{DD} ramps up and rises above a barrier voltage of 2V_{T}, the diode-connected transistors MN1 and MN2 enter a saturation region, resulting in a small resistance R_{U}. It is appreciated that the barrier voltage presented by the transistors MN1 and MN2 can be increased by adding one or more series transistors and can be reduced by removing one of the transistors. On the other hand, the diode-connected transistor MN3 is less susceptible to the supply voltage V_{DD} since it is reverse-biased. FIG. 3 shows that the equivalent resistance R_{D} becomes greater as the supply voltage V_{DD} increases. Note that the voltage V_{A} is a function of the equivalent resistance R_{U} and R_{D}. When the power supply is turned on and V_{DD} starts to ramp up, the transistor MN3 connects the ground potential to the junction A. Responding thereto, the inverter 212 provides a logic high level at its output, thus causing the inverter 216 to make the reset signal ˜RST low. As the supply voltage V_{DD} is ramping up, the power-on reset circuit 200 within an integrated circuit resets flip-flops, registers, and latches for example, so that the integrated circuit has a correct start up configuration or valid state when the power supply reaches the operational voltage for all parts of the circuit required to work. The reset signal ˜RST remains low until the voltage V_{A} rises above an activation voltage of the inverter 212. When the voltage V_{A} at the input of the inverter 212 exceeds the activation voltage, the signal RST goes low and the inverter 216 thereby causes the output ˜RST to become a logic high level. Meanwhile, the signal RST at a logic low level turns on the PMOS transistor MP1, which in turn pulls the voltage V_{A} up to the supply voltage V_{DD}. This leads the reset signal ˜RST to rapidly change high. Furthermore, the inverter 212 and the PMOS transistor MP1 latch the reset signal ˜RST at the logic high level after the output of the power supply exceeds the operational voltage, preventing it from fluctuating due to power noise and other reasons. The reset signal ˜RST stays high and remains so as long as the power supply keeps the voltage V_{A} high enough. Once the voltage V_{A} falls below the activation voltage due to power-off or power perturbation, the reset signal ˜RST returns low accordingly and is ready to initialize the state of an integrated circuit.

Without using a capacitor, the present invention provides an on-chip power-on reset circuit unencumbered by the limitations associated with related arts.

While the invention has been described by way of examples and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A power-on reset circuit comprising:
an inverter having an input terminal and an output terminal;
a switch means, coupled between a power supply and said input terminal of said inverter, having a control terminal coupled to said output terminal of said inverter;
a plurality of diode-connected transistors connected in series between said power supply and said input terminal of said inverter; and
another diode-connected transistor connected in inverse series with said plurality of diode-connected transistors and between said input terminal of said inverter and a circuit ground.

2. The power-on reset circuit of claim 1 wherein said another diode-connected transistor is arranged to be reverse-biased.

3. The power-on reset circuit of claim 1 wherein said diode-connected transistors are each implemented with a common drain-gate connected MOS transistor.

4. The power-on reset circuit of claim 1 wherein said switch means comprises a PMOS transistor.

5. The power-on reset circuit of claim 4 wherein said PMOS transistor has a gate connected to said control terminal, a source connected to said power supply, and a drain connected to said input terminal of said inverter.

6. An apparatus for generating a reset signal used in an integrated circuit upon power-on, comprising:
a plurality of diode-connected transistors connected in series between a power supply and a junction;
another diode-connected transistor connected in inverse series with said plurality of diode-connected transistors and between said junction and a circuit ground; and
a latch, coupled to said junction and latching said reset signal at a predetermined logic level when the output of said power supply exceeds an operational voltage.

7. The apparatus of claim 6 wherein said latch comprises:
an inverter having an input terminal connected to said junction and an output terminal providing said reset signal; and
a PMOS transistor having a gate connected to said output terminal of said inverter, a source connected to said power supply, and a drain connected to said input terminal of said inverter.

8. The apparatus of claim 6 wherein said another diode-connected transistor is arranged to be reverse-biased.

9. The apparatus of claim 6 wherein said diode-connected transistors are each implemented with a common drain-gate connected MOS transistor.

10. An apparatus for generating a reset signal used in an integrated circuit upon power-on, comprising:
a load means connected between a power supply and a junction;
a diode-connected transistor arranged to be reverse-biased and connected between said junction and a circuit ground; and
a latch, coupled to said junction and latching said reset signal at a predetermined logic level when the output of said power supply exceeds an operational voltage.

11. The apparatus of claim 10 wherein said load means comprises a plurality of second diode-connected transistors connected in series between said power supply and said junction.

12. The apparatus of claim 11 wherein said diode-connected transistors are each implemented with a common drain-gate connected MOS transistor.

13. The apparatus of claim 10 wherein said latch comprises:
an inverter having an input terminal connected to said junction and an output terminal providing said reset signal; and
a PMOS transistor having a gate connected to said output terminal of said inverter, a source connected to said power supply, and a drain connected to said input terminal of said inverter.
